(19) United States
(12) Patent Application Publication
(10) Pub. No.: US 2007/0037386 A1
(43) Pub. Date: Feb. 15, 2007

(54) Sloped thin film substrate edges

(76) Inventor: John L. Williams, Philomath, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/203,334

(22) Filed: Aug. 13, 2005

(51) Int. Cl. H01L 21/4763; H01L 21/302

(52) U.S. Cl. 438/640; 438/710; 257/E21.578

(57) ABSTRACT

A photoresist layer applied over a thin film substrate layer over a base substrate is patterned, resulting in an exposed portion of the thin film substrate layer. The photoresist layer and the exposed portion of the thin film substrate layer are physical plasma etched, resulting in the thin film substrate layer having sloped edges relative to the base substrate.

### BACKGROUND

Many semiconductor-fabricated electronic devices, such as micro electromechanical systems (MEMS) devices and thermal inkjet (TIJ) resistors, benefit from having thin film substrate edges sloped during fabrication. Examples of thin film materials include conductors like aluminum copper (AlCu), tantalum aluminide (TaAl), and titanium nitride (TiN), among other types of conductors, dielectrics like silicon carbide (SiC), undoped silicon glass (USG), silicon nitride (SiN), amorphous silicon, among other types of dielectrics, as well as other types of thin film materials. Sloping thin film substrate edges permits conductive, passivation, and other types of materials of the devices to likewise be sloped. For example, a thin film layer having a sloped hole allows another material deposited into the hole to likewise have a sloped profile. Such material is likely to be more structurally sound than material deposited into a hole that is not sloped. However, sloping the edges of a thin film substrate can be difficult to accomplish.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated.

FIG. 1 is a flowchart of a method for at least partially fabricating a semiconductor device, including sloping the edges of a thin film substrate layer during the fabrication of the device, according to an embodiment of the invention.

FIG. 2 is a diagram illustratively depicting the application of a photoresist layer to a thin film substrate layer of a semiconductor device being fabricated in accordance with the method of FIG. 1, according to an embodiment of the invention.

FIG. 3 is a diagram illustratively depicting the patterning of the photoresist layer of FIG. 2, in accordance with the method of FIG. 1, according to an embodiment of the invention.

FIG. 4A is a diagram illustratively depicting the heating of the photoresist layer of FIG. 3, in accordance with the method of FIG. 1, according to an embodiment of the invention.

FIG. 4B is a diagram illustratively depicting the physical plasma etching of the photoresist layer and the exposed portion of the thin film substrate layer of FIG. 3 or FIG. 4A, in accordance with the method of FIG. 1, according to an embodiment of the invention.

FIG. 5 is a diagram illustratively depicting the sloped thin film substrate layer of FIG. 4B after removal of the photoresist layer, in accordance with the method of FIG. 1, according to an embodiment of the invention.

FIG. 6 is a diagram illustratively depicting the deposition of material over the thin film substrate layer of FIG. 5, in accordance with the method of FIG. 1, according to an embodiment of the invention.

FIG. 7 is a diagram illustratively depicting the deposition of another material over the material deposited in FIG. 6, in accordance with the method of FIG. 1, according to an embodiment of the invention.

FIG. 8 is a diagram of an electronic device that may be formed at least in part by performing the method of FIG. 1, according to an embodiment of the invention.

### DETAILED DESCRIPTION OF THE DRAWINGS

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

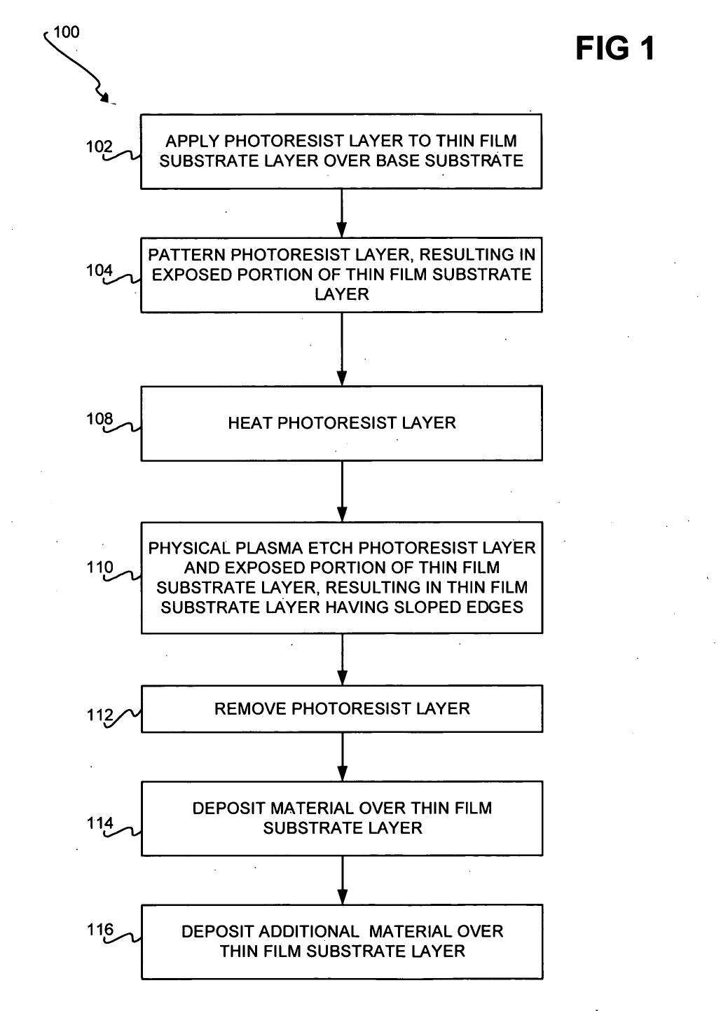

FIG. 1 shows a method 100 for sloping the edges of a thin film substrate layer of an electronic device, according to an embodiment of the invention. The method 100 may in one embodiment be employed to at least partially form or fabricate an electronic device. As can be appreciated by those of ordinary skill within the art, the method 100 may include other parts, in addition to and/or in lieu of those depicted in FIG. 1.

A photoresist layer is applied to a thin film substrate layer over a base substrate of an electronic device (102). The electronic device may be a micro electromechanical systems (MEMS) device, a thermal inkjet (TIJ) resistor device, or another type of electronic device. Examples of the base substrate include nonconductive substrates, such as phosphorous-doped glass (PDG), and tetraethyloxysilicate (TEOS), among other types of nonconductive substrates, and conductive substrates, such as aluminum (Al), aluminum copper (AlCu), and tantalum aluminide (TaAl), among other types of conductive substrates, as well as other types of base substrates. Examples of thin film substrate layers include conductors like aluminum copper (AlCu), tantalum aluminide (TaAl), and titanium nitride (TiN), among other types of conductors, dielectrics like silicon carbide (SiC), undoped silicon glass (USG), silicon nitride (SiN), amorphous silicon, among other types of dielectrics, as well as other types of thin film substrate layers. The layer of photoresist may also be referred to as a layer of resist, and can be applied to the substrate by spin-coating the substrate with photoresist. Photoresist is a light-sensitive material, similar to the coating on a regular photographic film.

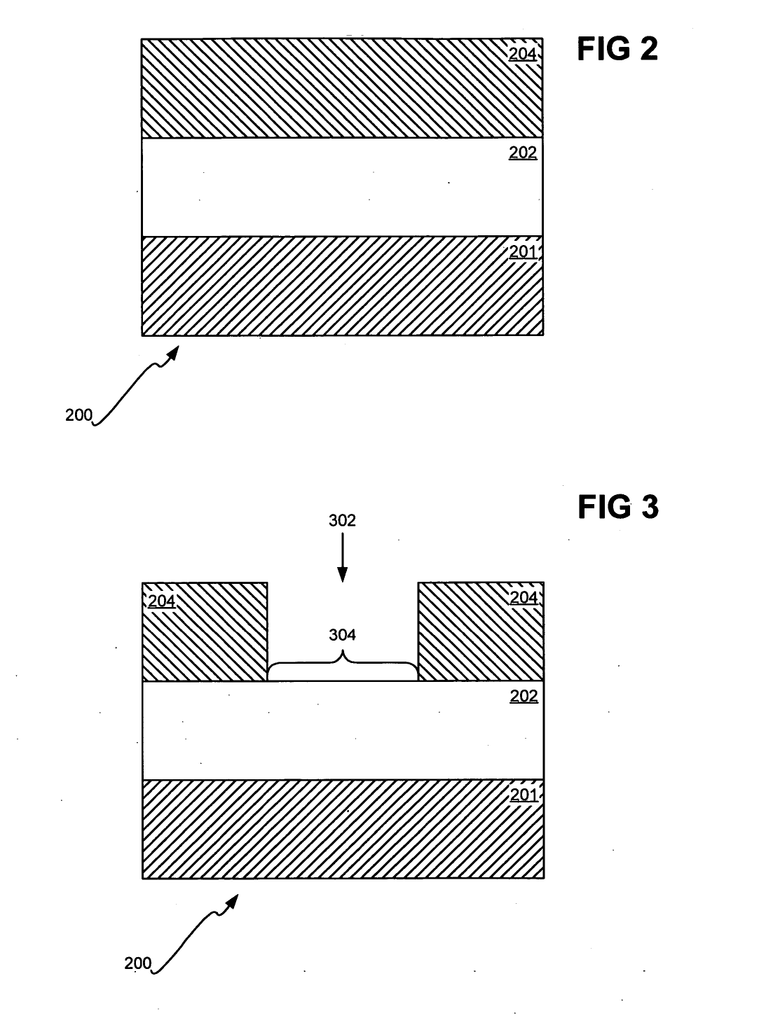

FIG. 2 illustratively depicts the application of a photoresist layer to a substrate in 102 of the method 100, according to an embodiment of the invention. An electronic device 200 includes a base substrate 201 and a thin film substrate layer 202 over the base substrate 201. A layer of photoresist 204 has been applied to the thin film substrate layer 202.

Referring back to FIG. 1, the photoresist layer is patterned, which results in a portion of the thin film substrate layer being exposed through the photoresist layer (104). The portion of the thin film substrate layer that becomes exposed as a result of patterning of the photoresist layer is referred to as the exposed portion of the thin film substrate layer. Patterning is also referred to as photolithography, photomasking, and microlithography. Patterning can create a pattern on the photoresist layer that corresponds to the features of the electronic device being fabricated. In general, the pattern of a reticle or photomask is typically transferred into a layer of photoresist, in a process known as exposure, such that only some parts of the photoresist layer are exposed to light. The photoresist layer is then developed to remove either the parts of the photoresist that were exposed to light, or the parts of the photoresist that were not exposed to light. The result is that the photoresist layer has a pattern corresponding to the pattern of the reticle or photomask employed during exposure.

FIG. 3 illustratively depicts the patterning of the photoresist layer in 104 of the method 100, according to an embodiment of the invention. The layer of photoresist 204 has been patterned to result in a feature 302 within the photoresist 204 that extends to the thin film substrate layer 202. The feature 302 may be a via, a hole, a trench, or a line edge, and the terminology feature is intended as a generic term meant to encompass these and other types of features. As a result of patterning of the photoresist 204, a portion 304 of the thin film substrate layer 202 becomes exposed, which is referred to as the exposed portion 304 of the thin film substrate layer 202.

Referring back to FIG. 1, the photoresist layer may be heated in one embodiment (108). Heating the photoresist layer can include hardbaking the electronic device on a hotplate. Heating the photoresist layer in one embodiment can specifically include hardbaking the electronic device on a hotplate at 135° C. for fifty seconds. Heating the photoresist causes it to soften and changes its sidewall profile, which promotes subsequently greater sloping of the edges of the thin film substrate layer.

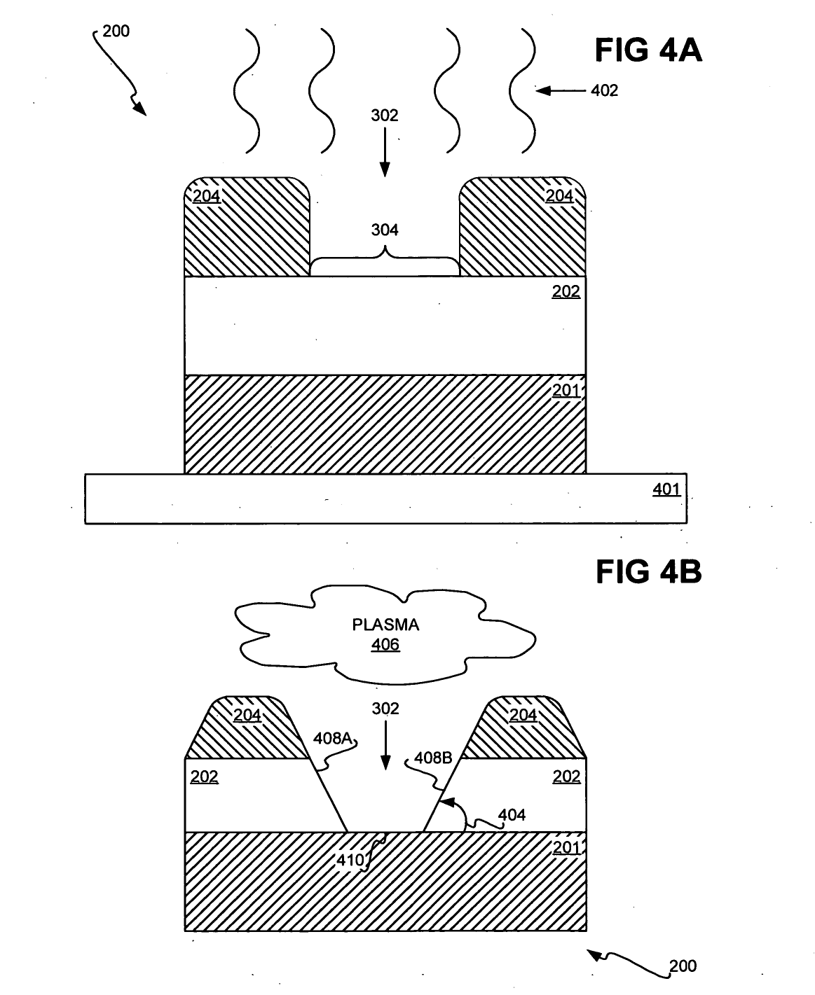

FIG. 4A illustratively depicts the heating of the photoresist layer in 108 of the method 100, according to an embodiment of the invention. In particular, the electronic device 200 has been placed on a hotplate 401, for baking the electronic device 200 to heat the layer of photoresist 204, as is indicated by the reference number 402. Heating the layer of photoresist 204 softens the photoresist 204. This is indicated in FIG. 4A by the corners of the edges of the photoresist 204 having rounded or softened corners as compared to the corners in FIG. 3.

Referring back to FIG. 1, a physical plasma etch of the photoresist layer and of the exposed portion of the substrate layer is performed that results in the thin film substrate layer having sloped edges (110). Physical plasma etching means that the electronic device is subjected to a plasma treatment that etches the exposed portion of the thin film substrate layer and the photoresist layer by physically bombarding these layers with plasma particles. Such physical plasma etching is in comparison to chemical plasma etching, in which the electronic device is subjected to a plasma treatment that etches the exposed portion of the thin film substrate and photoresist layers by plasma chemically reacting with these layers.

Thus, the physical plasma etching employs plasma etching parameters, which may also be referred to as a plasma etching recipe, that are adapted to physically etch both the photoresist layer and the exposed portion of the thin film substrate layer as opposed to chemically etching these layers. In one embodiment, the plasma etching parameters include a top radio-frequency (RF) power of 750 watts, and a bottom RF power of 400 watts. The plasma etching parameters further include a boron trichloride (BCl₃) flow rate of 120 standard cubic centimeters per minute (sccm), a chlorine (Cl₂) flow rate of 100 sccm, and a nitrogen (N₂) flow rate of 0 sccm (such that there is no nitrogen flow).

The angle of the slope of the edges of the thin film substrate layer relative to the base substrate of the electronic device is controlled by at least three factors. First, the length of time that the exposed portion of the thin film substrate layer is subjected to the physical plasma etching can control the angle of the slope of the edges of both the photoresist layer and the thin film substrate layer relative to the base substrate. In general, the longer the photoresist and the exposed portion of the thin film substrate layers are subjected to the physical plasma etching, the lesser the angle of the slope of the edges of the photoresist and of the thin film substrate layer relative to the base substrate becomes.

Second, whether or not the photoresist layer was previously heated in 108 of the method 100 can control the minimum angle of the slope of the edges of the photoresist layer and of the thin film substrate layer relative to the substrate. For instance, where the photoresist layer was previously heated, subsequent physical plasma etching of the photoresist layer and of the exposed portion of the thin film substrate layer may result in an angle of the slope of the edges of the photoresist layer and of the thin film substrate layer as small as about forty degrees, as desired. By comparison, where the photoresist layer was not previously heated, physical plasma etching of the photoresist layer and of the exposed portion of the thin film substrate layer may result in an angle of the slope of the edges of the photoresist layer and of the thin film substrate layer as small as about sixty degrees, as desired.

Third, the top-to-bottom power ratio of the physical etch recipe can control the angle of the slope of the edges of the photoresist layer and of the thin film layer relative to the base substrate. In general, the lower the top-to-bottom power ratio (such as either a lower top RF power or a higher bottom RF power), the lesser the angle of the slope of the edges of the photoresist and of the thin film substrate relative to the base substrate becomes.

FIG. 4B illustratively depicts the sloping of the edges of the thin film substrate layer in 106 of the method 100 via physical plasma etching, according to an embodiment of the invention. The layer of photoresist 204 and the exposed portion 304 of the thin film substrate layer 202 are subjected to physical plasma etching, as indicated by reference number 406. The plasma etchant physically bombards the photoresist 204 and the exposed portion 304 of the thin film substrate layer 202 to erode the exposed top layer of the photoresist 204 while physically etching the exposed portion 304 of the thin film substrate layer 202. This erosion of the top layer of the patterned photoresist 204 causes the patterned edge of the photoresist 204 to pull back during etching. As a result, edges 408A and 408B of the thin film substrate layer 202 and of the layer of photoresist 204, collectively referred to as the edges 408, become sloped.

The edges 408 of the thin film substrate layer 202 have an angle 404 relative to a top surface 410 of the base substrate 201 that reflects the sloped nature of their resulting profile. As has been noted, where the hardbaking or heating of FIG. 4A is performed, the angle 404 can be as small as about forty degrees, as desired. Where the hardbaking or heating of FIG. 4A is not performed, the angle 404 can be as small as about sixty degrees, as desired.

Referring back to FIG. 1, the photoresist layer is then removed (112). Removal of the photoresist layer can be accomplished by stripping the photoresist layer from the thin film substrate layer of the electronic device. The stripping may be accomplished in a wet manner, such as by immersing the photoresist layer within a chemical solution that chemically etches away the remaining photoresist. The stripping may also be accomplished in a dry manner, such as by subjecting the photoresist layer to a further plasma treatment that chemically or physically etches away the remaining photoresist.

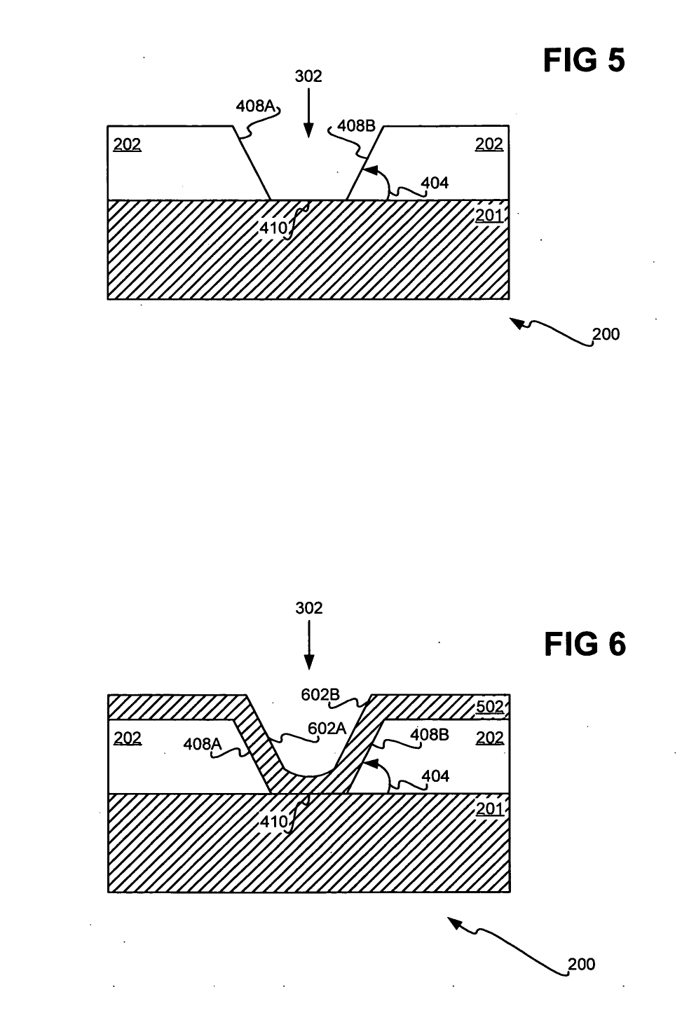

FIG. 5 illustratively depicts the removal of the remaining photoresist layer in 112 of the method 100, according to an embodiment of the invention. The layer of photoresist 204 of FIG. 4A 4B is no longer present in FIG. 5. Rather, just the etched and sloped thin film substrate layer 202 remains over the base substrate 201 of the electronic device 200 in FIG. 5. Stated another way, the feature 302 within the thin film substrate layer 202 is such that the edges 408 of the thin film substrate layer 202 are etched to either side of the feature 302.

Referring back to FIG. 1, in one embodiment a material may be deposited over the thin film substrate layer (114), the edges of which have been sloped. The sloped edges of the thin film substrate layer result in the material being deposited more uniformly over the complete surface of the etched and sloped thin film substrate layer. Therefore, voids, thin spots, and other imperfections are less likely to be created during the deposition process, so that the deposited material is more structurally sound and/or electronically continuous. The material may be a conductive material, such that the conductive material ultimately becomes a conductive trace of the electronic device, electrically connecting the base substrate to a subsequently applied layer over the conductive material. The material deposited in 114 may be referred to as a first material, to distinguish it from a second material that may be deposited in 116 of the method 100, as will be described.

FIG. 6 illustratively depicts the deposition of a material over the thin film substrate layer in 114 of the method 100, according to an embodiment of the invention. Specifically, a material 502 has been deposited over the thin film substrate layer 202. Due to the sloping of the edges 408 of the thin film substrate layer 202, the deposited material 502 uniformly covers the entirety of the electronic device 200. This is because the edges 408 of the thin film substrate layer 202 are sloped inwards. Thus, the material 502 has edges 602A and 602B, collectively referred to as the edges 602, which have slopes matching the slopes of the edges 408 of the etched thin film substrate layer 202. That is, the slopes of the edges 602 of the material 502 result from the sloping of the edges 408 of the thin film substrate layer 202. The material 502 may also be referred to as the first material 502.

Referring back to FIG. 1, another material may in one embodiment be deposited (116). The profile of the second material matches the sloped profile of the etched thin film substrate layer. Thus, the edges of the second material have a slope that matches the slope of the edges of the thin film substrate layer where the second material meets the first material previously deposited in 112. The sloped profile of the second material is therefore accomplished without having to perform any planarization, which may otherwise have to be performed to achieve this sloped profile, resulting in cost-effective fabrication of the electronic device. The second material may be a passivation material, such that the second material becomes a dielectric of the electronic device as sandwiched between two conductive portions of the electronic device.

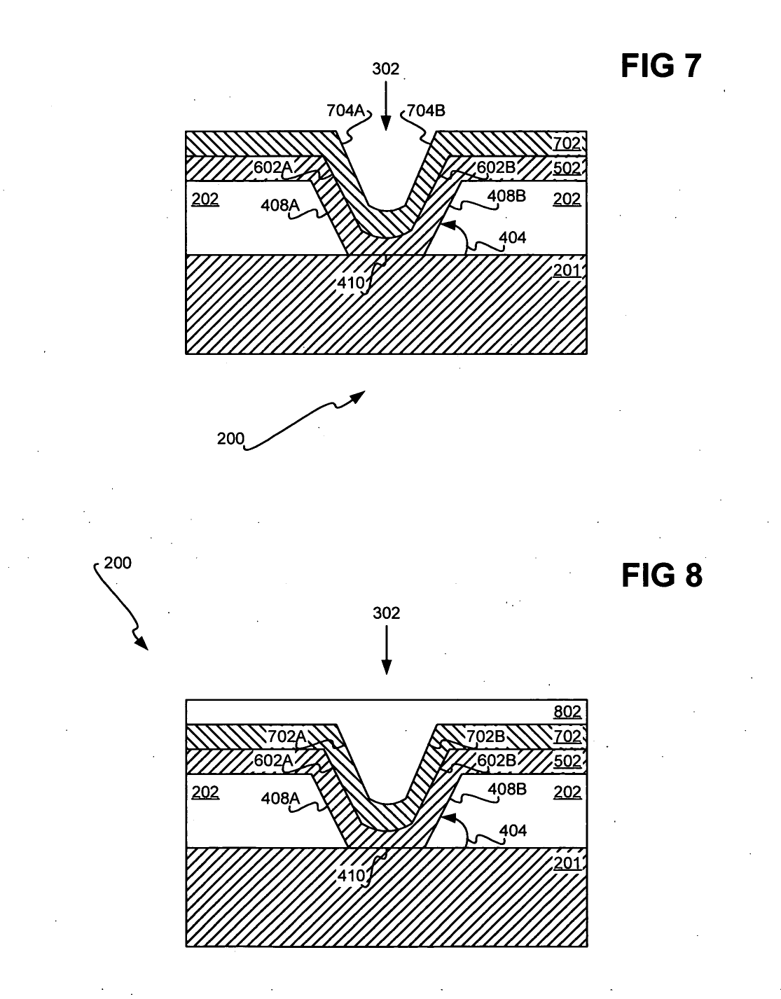

FIG. 7 illustratively depicts the deposition of a second material in 116 of the method 100, according to an embodiment of the invention. A second material 702 has been deposited over the material 502. Where the second material 702 meets the first material 502, its profile is the same as that of the etched and sloped thin film substrate layer 202 in FIG. 5. The second material 702 therefore has edges 704A and 704B, collectively referred to as the edges 704, which have slopes matching the slopes of the edges 408 of the thin film substrate layer 202 and matching the slopes of the edges 602 of the first material 502.

Finally, FIG. 8 shows a portion of a rudimentary electronic device 200 that may be fabricated or formed at least in part by performing the method 100 of FIG. 1 that has been described and illustratively depicted in relation to FIGS. 2-7, according to an embodiment of the invention. The electronic device 200 may be a MEMS device, a TIJ resistor device, or another type of electronic device. The electronic device 200 includes the base substrate 201, the sloped thin film substrate layer 202, the first material 502 and the second material 702 deposited over the thin film substrate layer 202, and a layer of a third material 802 deposited over the layer of the first and the second materials 502 and 702.

As has been described, the first material 502 may be a conductive material, whereas the second material 702 may be a non-conductive passivation material. Where the base substrate 201 contains conductive portions where the first material 502 meets the base substrate 201, the first material 502 may thus function or act as a vertical conductive trace. Furthermore, or alternatively, the second material 702 may function or act as a dielectric material for a capacitor having the first material 502 and the third material 802 as end plates, for instance.

It is noted that, although specific embodiments have been illustrated and described herein, it will be appreciated by those of ordinary skill in the art that any arrangement calculated to achieve the same purpose may be substituted for the specific embodiments shown. This application is thus intended to cover any adaptations or variations of the disclosed embodiments of the present invention. Therefore, it is manifestly intended that this invention be limited only by the claims and equivalents thereof.

We claim:

1. A method comprising:
patterning a photoresist layer applied over a thin film substrate layer over a base substrate, resulting in an exposed portion of the thin film substrate layer; and,
physical plasma etching the photoresist layer and the exposed portion of the thin film substrate layer, resulting in the thin film substrate layer having a plurality of sloped edges relative to the base substrate.

2. The method of claim 1, wherein physical plasma etching results in the edges of the thin film substrate layer having an angle relative to the base substrate that is as small as about sixty degrees.

3. The method of claim 1, further comprising heating the photoresist layer prior to physical plasma etching the photoresist layer and the exposed portion of the thin film substrate layer.

4. The method of claim 3, wherein physical plasma etching after heating the photoresist layer results in the edges of the thin film substrate layer having an angle relative to the base substrate that is as small as about forty degrees.

5. The method of claim 3, wherein heating the photoresist layer comprises hardbaking the substrate on a hotplate.

6. The method of claim 1, wherein physical plasma etching the photoresist layer and the exposed portion of the thin film substrate layer comprises using plasma etching parameters adapted to physically etch the photoresist and the thin film substrate layers as opposed to chemically etching the photoresist and the thin film substrate layers.

7. The method of claim 6, wherein the plasma etching parameters comprise:
a top radio-frequency (RF) power of 750 watts;
a bottom RF power of 400 watts;
a boron trichloride (BCl3) flow rate of 120 standard cubic centimeters per minute (sccm);
a chlorine (Cl2) flow rate of 100 sccm; and,
a nitrogen (N2) flow rate of 0 sccm.

8. An electronic device formed at least in part by a method comprising:
applying a photoresist layer to a thin film substrate layer over a base substrate;
patterning the photoresist layer, resulting in an exposed portion of the thin film substrate layer;
physical plasma etching the photoresist layer and the exposed portion of the thin film substrate layer, resulting in the thin film substrate layer having a plurality of sloped edges relative to the base substrate;
removing the photoresist layer; and,
depositing a material over thin film substrate layer.

9. The electronic device of claim 8, wherein physical plasma etching results in the edges of the thin film substrate layer having an angle relative to the base substrate that is as small as about sixty degrees.

10. The electronic device of claim 8, wherein the method further comprises heating the photoresist layer prior to physical plasma etching the photoresist layer and the exposed portion of the thin film substrate layer.

11. The electronic device of claim 10, wherein physical plasma etching after heating the photoresist layer results in the edges of the thin film substrate layer having an angle relative to the base substrate that is as small as about forty degrees.

12. The electronic device of claim 8, wherein physical plasma etching the photoresist layer comprises using plasma etching parameters comprising:
a top radio-frequency (RF) power of 750 watts;
a bottom RF power of 400 watts;
a boron trichloride (BCl3) flow rate of 120 standard cubic centimeters per minute (sccm);
a chlorine (Cl2) flow rate of 100 sccm; and,
a nitrogen (N2) flow rate of 0 sccm.

13. The electronic device of claim 8, wherein the material deposited over the thin film substrate layer is a first material, and the method further comprises depositing a second material over the first material.

14. The electronic device of claim 8, wherein the electronic device is one of a micro electromechanical systems (MEMS) device, or a thermal inkjet (TIJ) resistor device.

15. An electronic device comprising:
a base substrate; and,
a thin film substrate layer having a plurality of edges that are sloped relative to the base substrate by at least physical plasma etching.

16. The electronic device of claim 15, wherein the edges are sloped relative by heating a patterned photoresist layer temporarily applied to the thin film substrate layer, prior to physical plasma etching.

17. The electronic device of claim 15, wherein the edges are sloped relative to the base substrate by physical plasma etching using plasma etching parameters comprising:
a top radio-frequency (RF) power of 750 watts;
a bottom RF power of 400 watts;
a boron trichloride (BCl3) flow rate of 120 standard cubic centimeters per minute (sccm);
a chlorine (Cl2) flow rate of 100 sccm; and,
a nitrogen (N2) flow rate of 0 sccm.

18. The electronic device of claim 15, further comprising a material deposited over the thin film substrate layer.

19. The electronic device of claim 18, wherein the material comprises a conductive material that is a conductive trace of the electronic device.

20. The electronic device of claim 18, wherein the material has edges that are sloped and match sloping of the edges of the thin film substrate layer.

21. The electronic device of claim 18, wherein the material deposited over the thin film substrate layer is a first material, and the electronic device further comprises a second material deposited over the first material.

22. The electronic device of claim 21, wherein the second material comprises a passivation material that is a dielectric of the electronic device.

23. The electronic device of claim 21, wherein the second material has edges that are sloped and match sloping of the edges of the thin film substrate layer.

24. The electronic device of claim 15, wherein the electronic device is one of a micro electromechanical systems (MEMS) device, or a thermal inkjet (TIJ) resistor device.

25. An electronic device comprising:
a base substrate;
a thin film substrate layer having a plurality of edges; and,
means for sloping the edges of the thin film substrate layer by at least physical plasma etching.

26. The electronic device of claim 25, wherein the means comprises a patterned photoresist layer.

27. The electronic device of claim 25, wherein the means is for sloping the edges of the thin film substrate layer further by preheating prior to physical plasma etching.

28. The electronic device of claim 25, further comprising a material deposited over the thin film substrate layer upon removal of the means after the edges of the thin film substrate layer have been sloped.

29. The electronic device of claim 28, wherein the material deposited over the thin film substrate layer is a first layer, and the electronic device further comprises a second material deposited over the first material.

30. The electronic device of claim 25, wherein the electronic device is one of a micro electromechanical systems (MEMS) device, or a thermal inkjet (TIJ) resistor device.
